(19) United States
(12) Patent Application Publication
(10) Pub. No.: US 2005/0013161 A1
(43) Pub. Date: Jan. 20, 2005

(54) Ferroelectric memory and method of manufacturing the same

(75) Inventors: Akihito Matsumoto, Suwa-shi (JP); Eiji Natori, Chino-shi (JP); Tatsuya Shimoda, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/771,353

(22) Filed: Feb. 5, 2004

(30) Foreign Application Priority Data
Feb. 6, 2003 (JP) 2003-29657

(51) Int. Cl. G11C 11/14

(52) U.S. Cl. 365/171

(57) ABSTRACT

A ferroelectric memory of the present invention includes a sheet-shaped device including a memory cell array which includes a ferroelectric capacitor, and a circuit section which is formed on the memory cell array and includes a thin-film transistor.

Japanese Patent Application No. 2003-29657, filed on Feb. 6, 2003, is hereby incorporated by reference in its entirety.

### BACKGROUND OF THE INVENTION

The present invention relates to a ferroelectric memory and a method of manufacturing the same.

In recent years, a ferroelectric memory (FeRAM) utilizing a ferroelectric capacitor which retains data by spontaneous polarization has attracted attention. In a so-called cross-point ferroelectric memory, a ferroelectric capacitor and a MOS transistor need not be formed in a one-to-one configuration, and a memory cell can be formed only by the ferroelectric capacitor. This simplifies the structure, whereby an increase in the degree of integration is expected.

In the cross-point ferroelectric memory, even if the area of the memory cell array region is decreased, a control circuit is necessarily formed around the memory cell array. Specifically, since a large area is necessary for the entire ferroelectric memory, a further improvement has been demanded in order to increase the degree of integration.

### BRIEF SUMMARY OF THE INVENTION

The present invention may provide a ferroelectric memory in which the degree of integration can be further increased.

A ferroelectric memory according to the present invention includes a sheet-shaped device including a memory cell array which includes a ferroelectric capacitor, and a circuit section which is formed over the memory cell array and includes a thin-film transistor.

A method of manufacturing a ferroelectric memory according to the present invention includes:
(a) forming a memory cell array including a ferroelectric capacitor; and
(b) forming a circuit section including a thin-film transistor over the memory cell array to form a sheet-shaped device.

Another method of manufacturing a ferroelectric memory according to the present invention includes:
(a) forming a separation layer which changes upon absorbing light on a first substrate which is capable of transmitting the light;
(b) forming a memory cell array and a circuit section on the separation layer to form a sheet-shaped device, the memory cell array including a ferroelectric capacitor, and the circuit section being disposed on the memory cell array and including a thin-film transistor;
(c) bonding the first substrate and a second substrate through at least an adhesive layer, the sheet-shaped device being formed on the first substrate; and
(d) removing the sheet-shaped device from the first substrate by applying light to the separation layer from one side of the first substrate.

### BRIEF DESCRIPTION OF THE SEVERAL VIEWS OF THE DRAWING

FIG. 1 is a plan view schematically showing a ferroelectric memory according to a first embodiment.

FIGS. 2A and 2B are cross-sectional views schematically showing a ferroelectric memory according to the first embodiment.

FIG. 3 is a cross-sectional view schematically showing a step of a manufacturing method in the first embodiment.

FIG. 4 is a cross-sectional view schematically showing a step of the manufacturing method in the first embodiment.

FIG. 5 is a cross-sectional view schematically showing a step of the manufacturing method in the first embodiment.

FIG. 6 is a cross-sectional view schematically showing a step of the manufacturing method in the first embodiment.

FIG. 7 is a cross-sectional view schematically showing a ferroelectric memory according to a modification.

FIG. 8 is a cross-sectional view schematically showing a ferroelectric memory according to a modification.

FIG. 9 is a cross-sectional view schematically showing a ferroelectric memory according to a second embodiment.

FIG. 10 is a cross-sectional view schematically showing a step of a manufacturing method according to the second embodiment.

FIG. 11 is a cross-sectional view schematically showing a step of the manufacturing method according to the second embodiment.

FIG. 12 is a cross-sectional view schematically showing a step of the manufacturing method according to the second embodiment.

FIG. 13 is a cross-sectional view schematically showing a step of a manufacturing method according to a modification of the second embodiment.

FIG. 14 is a cross-sectional view schematically showing a step of the manufacturing method according to the modification of the second embodiment.

FIG. 15 is a cross-sectional view schematically showing a step of the manufacturing method according to the modification of the second embodiment.

### DETAILED DESCRIPTION OF THE EMBODIMENT

An example of embodiments of the present invention is described below.

A ferroelectric memory according to an embodiment of the present invention includes a sheet-shaped device including a memory cell array which includes a ferroelectric capacitor, and a circuit section which is formed over the memory cell array and includes a thin-film transistor.

The ferroelectric memory according to this embodiment of the present invention includes the sheet-shaped device in which the circuit section which controls the operation of the memory cell is formed above the memory cell array. The circuit section used herein may include a circuit for writing data into the memory cell and a circuit for reading data from the memory cell. In the sheet-shaped device according to the present invention, it is unnecessary to provide the circuit section around the memory cell array. Therefore, area efficiency of the ferroelectric memory can be increased, whereby the size of the ferroelectric memory can be reduced.

The ferroelectric memory according to this embodiment of the present invention may include the following features.

With the ferroelectric memory according to this embodiment, a plurality of the sheet-shaped devices may be stacked. With this feature, since the plurality of sheet-shaped devices are stacked, high integration of a ferroelectric memory can be realized.

With the ferroelectric memory according to this embodiment, a semiconductor layer of the thin-film transistor may be a polysilicon layer.

With the ferroelectric memory according to this embodiment, the memory cell array may includes a plurality of first electrodes which are arranged in lines, a plurality of second electrodes which intersect the first electrodes, and a ferroelectric layer which is disposed at least in each of intersecting regions of the first electrodes and the second electrodes.

According to this feature, since the memory cell array can be formed only by the ferroelectric capacitors, the degree of integration of the ferroelectric memory can be increased.

The ferroelectric memory according to this embodiment may further include a peripheral circuit section which is formed around the sheet-shaped device.

According to this feature, control circuits can be separately formed depending on the necessity.

With the ferroelectric memory according to this embodiment, the peripheral circuit section may include a thin-film transistor.

According to this feature, since the peripheral circuit section is formed by thin semiconductor devices, the degree of integration of the ferroelectric memory can be increased.

With the ferroelectric memory according to this embodiment, the ferroelectric layer may include silicon and germanium in constituent elements at a ratio of 0≦germanium/silicon≦10.

A first method of manufacturing a ferroelectric memory according to an embodiment of the present invention includes:
(a) forming a memory cell array including a ferroelectric capacitor; and
(b) forming a circuit section including a thin-film transistor over the memory cell array to form a sheet-shaped device.

According to the first method of manufacturing a ferroelectric memory according to this embodiment, the circuit section can be formed on the memory cell array. As a result, area efficiency of the ferroelectric memory can be increased.

A second method of manufacturing a ferroelectric memory according to an embodiment of the present invention, includes:
(a) forming a separation layer which changes upon absorbing light on a first substrate which is capable of transmitting the light;
(b) forming a memory cell array and a circuit section on the separation layer to form a sheet-shaped device, the memory cell array including a ferroelectric capacitor, and the circuit section being disposed on the memory cell array and including a thin-film transistor;
(c) bonding the first substrate and a second substrate through at least an adhesive layer, the sheet-shaped device being formed on the first substrate; and
(d) removing the sheet-shaped device from the first substrate by applying light to the separation layer from one side of the first substrate.

According to the second method of manufacturing a ferroelectric memory according to this embodiment, a novel ferroelectric memory can be manufactured by removing the sheet-shaped device in which the circuit section is formed over the memory cell array from the first substrate.

The second method of manufacturing a ferroelectric memory according to this embodiment, may include:
bonding through an adhesive layer the sheet-shaped device that has been removed from the first substrate and a sheet-shaped device that is formed on a third substrate, on which is formed the sheet-shaped device, through a separation layer; and
removing the third substrate by applying light from one side of the third substrate, and
a plurality of the sheet-shaped devices may be stacked on the second substrate by repeatedly performing these steps one or more times.

According to this feature, since the sheet-shaped devices can be stacked, the degree of integration of the ferroelectric memory can be increased.

The first and second methods of manufacturing a ferroelectric memory according to the embodiments of the present invention may include the following features.

(A) The method of manufacturing a ferroelectric memory according to this embodiment, may include forming an insulating layer on the memory cell array, forming an amorphous silicon layer in a predetermined region of the insulating layer, and forming a polysilicon layer for the thin-film transistor by crystallizing the amorphous silicon layer by applying laser light, when forming the sheet-shaped device.

According to this feature, the thin-film transistor can be formed in a desired region of the memory cell array.

(B) The method of manufacturing a ferroelectric memory according to this embodiment, may include forming first electrodes which are arranged in lines, a ferroelectric layer which is disposed above each of the first electrodes, and second electrodes which are disposed in lines above the ferroelectric layer and intersecting the first electrodes, when forming the memory cell array.

According to this feature, since the memory cell array can be formed only by the ferroelectric capacitors, a memory cell array having a simple structure can be formed, whereby the degree of integration can be further increased.

(C) The method of manufacturing a ferroelectric memory according to this embodiment, may include forming a peripheral circuit section including a thin-film transistor around the sheet-shaped device.

(D) With the method of manufacturing a ferroelectric memory according to this embodiment, the ferroelectric layer may include silicon and germanium in constituent elements at a ratio of 0≦germanium/silicon≦10.

According to this feature, since the temperature when forming the ferroelectric layer can be decreased, the ferroelectric memory can be formed by using a low-temperature process.

The ferroelectric memory and the method of manufacturing the same according to the embodiment of the present invention are described below in more detail with reference to the drawings.

1. First Embodiment

1.1 Ferroelectric Memory

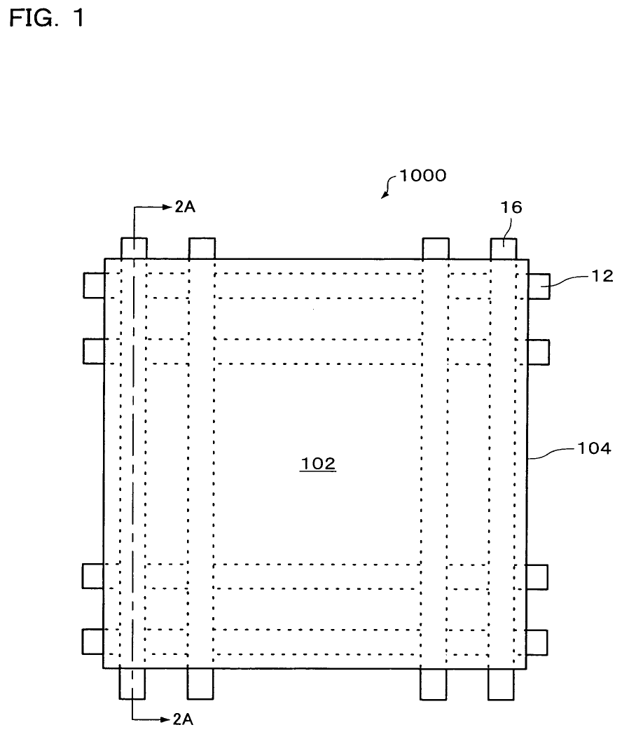

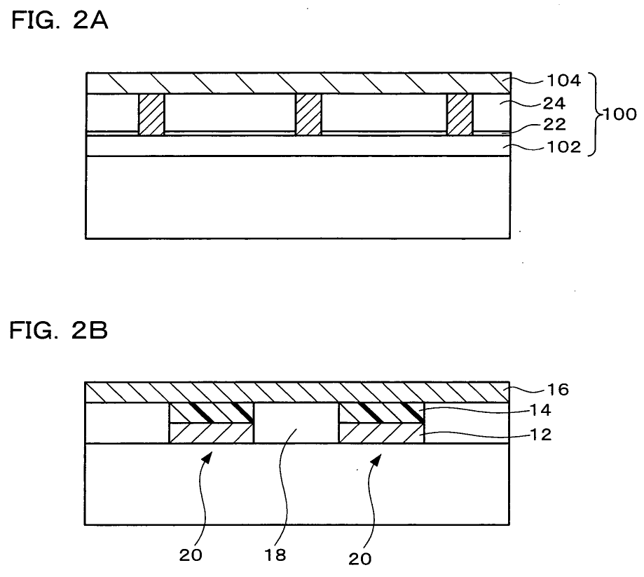

A ferroelectric memory 1000 according to the first embodiment is described below with reference to FIGS. 1, 2A, and 2B. In the following description of the embodiment, a ferroelectric memory including a memory cell array which includes a ferroelectric capacitor formed by a linear first electrode, a linear second electrode which intersects the first electrode, and a ferroelectric layer located in the intersecting region of the first electrode and the second electrode is illustrated as an example.

FIG. 1 is a plan view schematically showing a ferroelectric memory according to the first embodiment. FIG. 2A is a cross-sectional view schematically showing a part of the ferroelectric memory along the line 2A-2A shown in FIG. 1. FIG. 2B is an enlarged cross-sectional view showing a memory cell array 102. In FIG. 1, a region indicated by a dashed line is located in a layer lower than a region indicated by a solid line.

A ferroelectric memory 1000 in the present embodiment includes a sheet-shaped device 100 which includes the memory cell array 102 and a circuit section 104. As shown in FIGS. 1 and 2A, the circuit section 104 is formed on the memory cell array 102.

The memory cell array 102 is described below. In the memory cell array 102, a first electrode 12 (wordline) for selecting a row and a second electrode 16 (bitline) for selecting a column are arranged to intersect at right angles. Specifically, the first electrodes 12 are arranged at a predetermined pitch along the direction X, and the second electrodes 16 are arranged at a predetermined pitch along the direction Y which intersects the direction X at right angles. The first electrode 12 may be a bitline, and the second electrode 16 may be a wordline. A ferroelectric layer 14 is disposed in the intersecting region of the first electrode and the second electrode, and ferroelectric capacitors 20 (memory cells), each of which includes the first electrode 12, the ferroelectric layer 14, and the second electrode 16, are disposed in a matrix.

As shown in FIG. 2B, an insulating layer 18 is formed between the ferroelectric capacitors 20. The first electrode 12 and the second electrode 16 are prevented from short-circuiting by forming the insulating layer 18. The insulating layer 18 preferably includes a film which has insulating properties and functions as a hydrogen barrier.

As shown in FIG. 2B, a hydrogen barrier film 22 is formed on the memory cell array 102. The ferroelectric layer 14 of the ferroelectric capacitor 20 can be prevented from being reduced by forming the hydrogen barrier film 22. An insulating layer 24 is formed on the hydrogen barrier film 22. The circuit section 104 is disposed on the insulating layer 24. The circuit section 104 has at least a function of writing data into the memory cell of the memory cell array 102 or reading data from the memory cell. In more detail, the circuit section 104 includes a driver circuit and a signal detection circuit for selectively controlling the first electrode 12 and the second electrode 16 and the like. As specific examples of these circuits, a Y gate, sense amplifier, input/output buffer, X address decoder, Y address decoder, address buffer, and the like can be given. The circuit section 104 is formed by thin semiconductor devices such as thin-film transistors.

Since the ferroelectric memory 1000 in the present embodiment includes the sheet-shaped device 100 in which the circuit section 104 is formed on the memory cell array 102, the ferroelectric memory 1000 in which area efficiency is improved can be provided. Moreover, since the circuit section 104 is formed by thin semiconductor devices such as thin-film transistors, a thin ferroelectric memory can be provided.

1.2 Method of Manufacturing Ferroelectric Memory

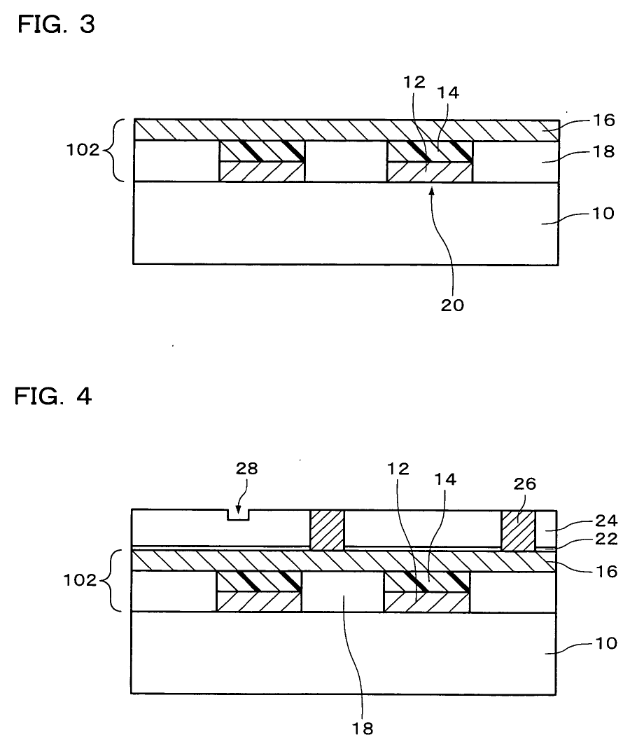

An example of a method of manufacturing the ferroelectric memory 1000 shown in FIGS. 1, 2A, and 2B is described below. FIGS. 3 to 8 are cross-sectional views schematically showing manufacturing steps of the ferroelectric memory 1000.

(1) As shown in FIG. 3, the memory cell array 102 including the ferroelectric capacitor 20 is formed. The memory cell array 102 may be formed as described below, for example.

A first conductive layer for forming the first electrode 12 is formed on a substrate 10. The material for the first conductive layer is not particularly limited insofar as the first conductive layer can become the electrode of the ferroelectric capacitor. As examples of the material for the first conductive layer, Ir, IrOₓPt, RuOₓ, SrRuOₓ, and LaSrCoOₓ can be given. The first conductive layer may be either a single layer or a number of stacked layers. For example, an adhesive layer such as TiOₓ may be formed under the conductive material. As the formation method for the first conductive layer, a method such as sputtering, vacuum deposition, CVD, or the like may be used.

A ferroelectric layer is formed on the first conductive layer. As the material for the ferroelectric layer 14, a material having an arbitrary composition may be used insofar as the material exhibits ferroelectricity and can be used as a capacitor insulating film. As examples of such ferroelectrics, PZT (PbZr_{z}Ti_{1-z}O₃) and SBT (SrBi₂Ta₂O₉) can be given. A material in which a metal such as niobium, nickel, or magnesium is added to the above material may also be applied. As the formation method for the ferroelectric layer, a spin coating method or a dipping method using a sol-gel material or an MOD material, a sputtering method, an MOCVD method, and a laser ablation method can be given.

The ferroelectric layer may include both silicon and germanium in the constituent elements. In this case, the ferroelectric layer may be formed by crystallizing a mixture of a sol-gel material of a paraelectric such as a layered compound having an oxygen tetrahedral structure consisting of a mixture of at least one oxide selected from the group consisting of CaO, BaO, PbO, ZnO, MgO, B₂O₃, Al₂O₃, Y₂O₃, La₂O₃, Cr₂O₃, Bi₂O₃, Ga₂O₃, ZrO₂, TiO₂, HfO₂, NbO₂, MoO₃, WO₃, and V₂O₅, and SiO₂ or SiO₂ and GeO₂, and a sol-gel material of a ferroelectric such as PZT or SBT. According to this formation method, since the component such as Si or Ge functions as a catalyst, the crystallization temperature can be decreased.

The first electrode 12 having a predetermined pattern is formed by using a conventional lithographic and etching technology. In this case, the ferroelectric layer is also etched in the same pattern as that of the first electrode 12. The insulating layer 18 is then formed so that the space between the laminates consisting of the first electrode 12 and the ferroelectric layer are filled with the insulating layer 18. As the material for the insulating layer 18, silicon oxide or the like can be given. As the formation method for the insulating layer 18, a CVD method or the like can be given.

A third conductive layer (not shown) which becomes the second electrode 16 is deposited. The material and the formation method for the third conductive layer may be the same as the material and the formation method for the first conductive layer, for example.

The third conductive layer and the ferroelectric layer are etched by using a conventional lithographic and etching technology, whereby the second electrode 16 having a predetermined pattern is formed. The ferroelectric layer 14 is formed in the intersecting region of the second electrode 16 and the first electrode 12 by patterning the ferroelectric layer. The insulating layer 18 remains under the second electrode 16 in the region other than the intersecting region of the second electrode 16 and the first electrode 12. The memory cell array 102 is formed in this manner.

As shown in FIG. 4, the hydrogen barrier film 22 is formed on the memory cell array 102, if necessary. The material for the hydrogen barrier film 22 is not particularly limited insofar as the material can prevent the ferroelectric layer 14 from being reduced by hydrogen. As examples of such a material, aluminum oxide, titanium oxide, and magnesium oxide can be given. As the formation method for the hydrogen barrier film 22, a sputtering method, a CVD method, and a laser ablation method can be given. The insulating layer 24 is then formed on the hydrogen barrier film 22. An insulating layer such as a silicon oxide layer may be formed as the insulating layer 24.

(2) The circuit section 104 is formed on the memory cell array.

A plug 26 which electrically connects the memory cell array 102 with the circuit section 104 is formed in the insulating layer 24 by using a conventional interconnect formation technology.

As shown in FIG. 4, a recess section 28 is formed in a predetermined region of the insulating layer 24 by using a conventional lithographic and etching technology. Although not shown in the drawing, a plurality of semiconductor devices such as thin-film transistors are formed in the circuit section 104. The recess section 28 has a width of 100 nm and a depth of 750 nm, for example.

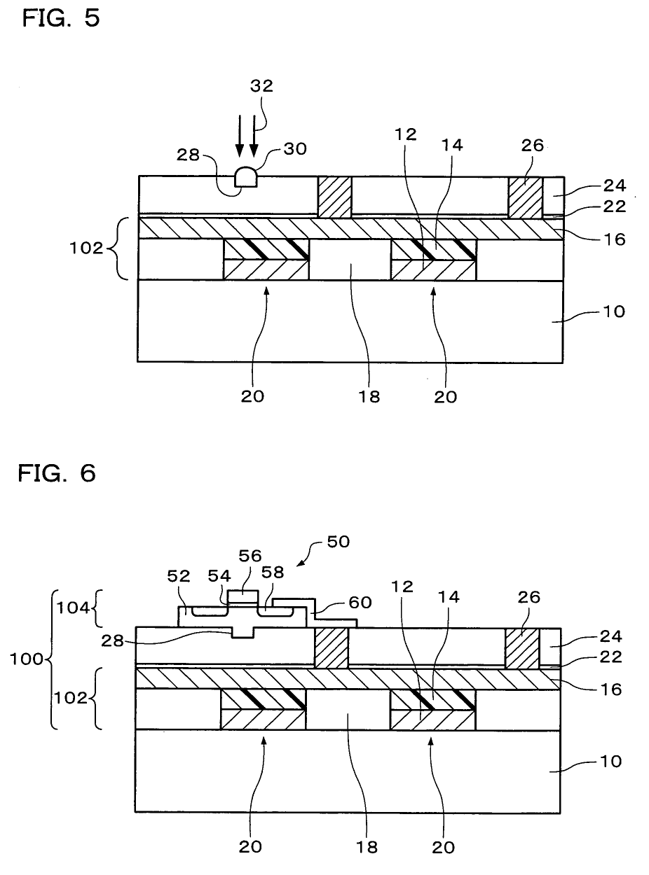

(3) As shown in FIG. 5, an amorphous silicon layer 30 is formed in the recess section 28. The amorphous silicon layer 30 may be formed by using an LPCVD method, for example. A laser beam 32 is then applied to the amorphous silicon layer 30.

(4) As shown in FIG. 6, the amorphous silicon layer 30 is crystallized by applying laser beam, whereby a polysilicon layer 52 is formed. According to this method, the polysilicon layer 52 can be formed only in a desired region of the insulating layer 24. The details of this technology are described in SPIE Vol. 4295.

A gate insulating layer 54 and a gate electrode 56 are formed on the polysilicon layer 52 by using a conventional MOS transistor formation technology. An impurity layer 58 which becomes a source region and a drain region is formed on each side of the gate electrode 56. A thin-film transistor 50 is formed in this manner. The thin-film transistor 50 is connected with the plug 26 through an interconnect layer 60. The circuit section 104 is formed in this manner, whereby the ferroelectric memory 1000 including the sheet-shaped device 100 according to the present embodiment is formed. The advantages of the manufacturing method in the present embodiment are described below.

(A) According to the manufacturing method of the ferroelectric memory 1000 in the present embodiment, a ferroelectric memory in which the circuit section 104 is stacked on the memory cell array 102 can be manufactured. This increases area efficiency, whereby a reduction of size and an increase in capacity of the ferroelectric memory can be achieved.

(B) According to the manufacturing method in the present embodiment, the thin-film transistor 50 is formed after forming the memory cell array 102. Therefore, since the thin-film transistor 50 is not subjected to a heat treatment at 600° C. to 700° C. which is necessary for crystallizing the ferroelectric layer, deterioration of the characteristics can be prevented.

(C) According to the manufacturing method of the polysilicon layer 52 in the present embodiment, the thin-film transistor 50 can be formed at a desired position of the insulating layer 24 located on the memory cell array 102. Therefore, the circuit section 104 can be easily formed on the memory cell array 102.

1.3 Modification

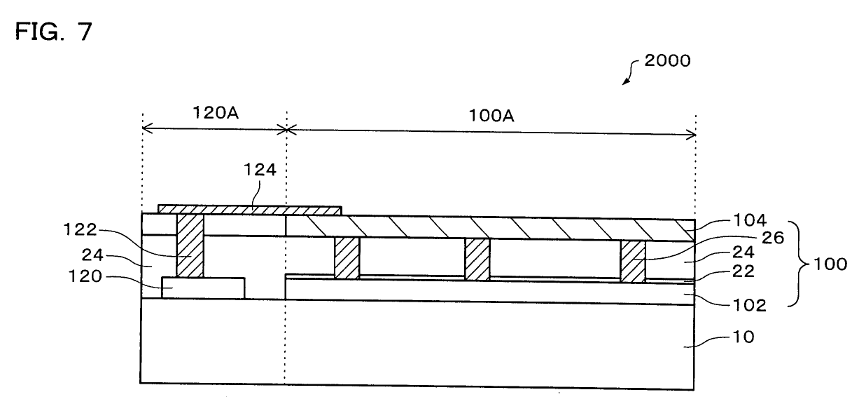

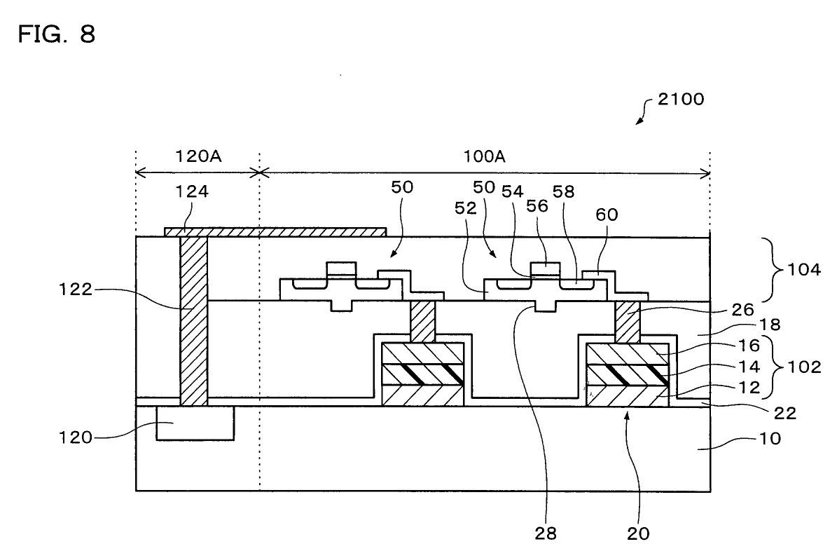

FIGS. 7 and 8 are cross-sectional views schematically showing ferroelectric memories 2000 and 2100 according to modifications of the first embodiment.

In the ferroelectric memory 2000, a peripheral circuit region 120A is formed around a sheet-shaped device region 100A in which the memory cell array 102 and the circuit section 104 are formed, as shown in FIG. 7. A peripheral circuit section 120 is included in the peripheral circuit region 120A, and is formed by MOS transistors formed on a bulk semiconductor layer, thin-film transistors, and the like. The insulating layer 24 is formed on the peripheral circuit section 120. A plug 122 is formed in the insulating layer 24 in order to provide electrical connection with the circuit section 104. The peripheral circuit section 120 is electrically connected with the circuit section 104 through the plug 122 and an interconnect layer 124.

A manufacturing method of the ferroelectric memory 2000 shown in FIG. 7 is described below. A semiconductor device such as a MOS transistor which makes up the peripheral circuit section 120 is formed on a semiconductor substrate (not shown) which is a part of the substrate 10. The peripheral circuit section 120 including a MOS transistor may be formed as described below. An element isolation region is formed in a predetermined region of the semiconductor substrate by using a trench isolation method, a LOCOS method, or the like. Then, a gate insulating layer and a gate electrode are formed, and source/drain regions are formed by doping the semiconductor substrate with impurities. An interlayer dielectric is formed on the semiconductor substrate 10 including the MOS transistor by using a conventional method.

In the case of forming the peripheral circuit section 120 including a thin-film transistor, the thin-film transistor may be formed by performing the same steps as the steps (2) to (4) in the first embodiment.

The memory cell array 102 and the circuit section 104 are formed in the same manner as in the manufacturing method in the first embodiment, whereby the ferroelectric memory 2000 is formed.

The ferroelectric memory 2100 shown in FIG. 8 is an example in which the present embodiment is applied to a 1T1C ferroelectric memory. In the sheet-shaped device region 100A, the memory cell array 102 including the ferroelectric capacitor 20 consisting of the first electrode 12, the ferroelectric layer 14, and the second electrode 16 is formed on the substrate 10. The circuit section 104 including the thin-film transistor 50 is formed on the memory cell array 102 through the insulating layer 18. The plug 26 is formed in the insulating layer 18 in order to electrically connect the ferroelectric capacitor 20 with the thin-film transistor 50. In this case, the thin-film transistor 50 in the circuit section 104 functions as a select transistor. The thin-film transistor 50 may be configured in the same manner as in the first embodiment. The thin-film transistor 50 is electrically connected with the plug 26 through the interconnect layer 60. The peripheral circuit region 120A may be configured in the same manner as that of the ferroelectric memory 2000 shown in FIG. 7. The hydrogen barrier film 22 may be formed between the ferroelectric capacitor 20 and the insulating layer 18 by using a material which can prevent the ferroelectric layer 14 from being reduced by hydrogen, such as aluminum oxide, titanium oxide, or magnesium oxide, if necessary. As the formation method for the hydrogen barrier film 22, a sputtering method, a CVD method, and a laser ablation method can be given.

According to this modification, circuits which control the ferroelectric memories 2000 and 2100 can be separately formed in the circuit section 104 and the peripheral circuit section 120. As a result, the degree of integration of the ferroelectric memory can be increased. In the case of the 1T1C ferroelectric memory 2100 shown in FIG. 8, the area of the memory cell array 102 can be reduced by forming the select transistor above the ferroelectric capacitor 20.

2. Second Embodiment

2.1. Structure of Ferroelectric Memory

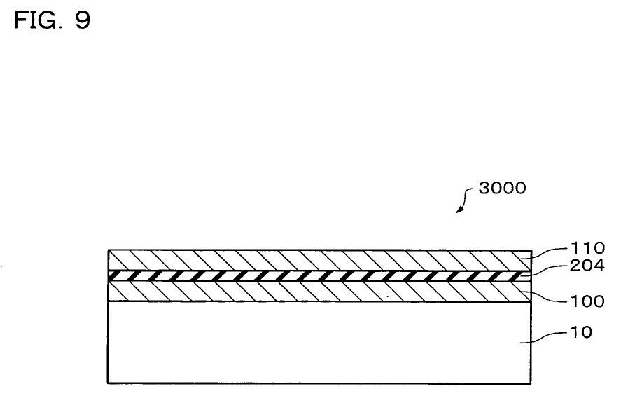

A ferroelectric memory 3000 in the second embodiment is described below with reference to FIG. 9. FIG. 9 is a cross-sectional view schematically showing the ferroelectric memory 3000 in the second embodiment. In FIG. 9, sections having substantially the same functions as the sections shown in FIGS. 1 and 2 are denoted by the same symbols. Detailed description of these sections is omitted.

In the ferroelectric memory 3000, a first sheet-shaped device 100 and a second sheet-shaped device 110 are stacked on the substrate 10, as shown in FIG. 9. The first and second sheet-shaped devices 100 and 110 have the same structure as that of the sheet-shaped device 100 described in the first embodiment, and are connected through an adhesive layer 204. As examples of the adhesive layer, various adhesives such as a reaction curable adhesive, a heat curable adhesive, and a photocurable adhesive such as a UV-curable adhesive can be given.

According to the ferroelectric memory 3000 in the present embodiment, a ferroelectric memory in which the degree of integration can be further increased by stacking the first and second sheet-shaped devices 100 and 110 can be provided.

2.2 Method of Manufacturing Ferroelectric Memory

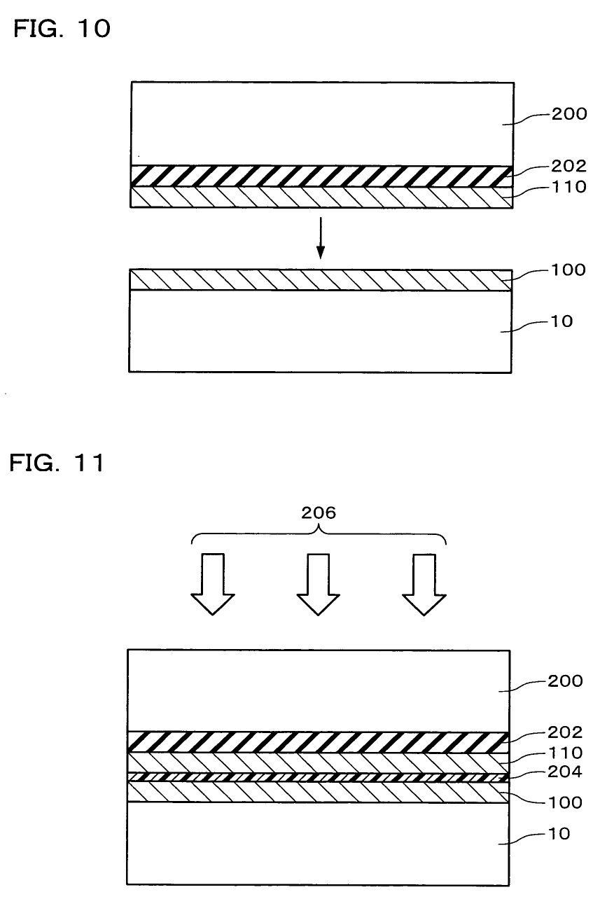

A method of manufacturing the ferroelectric memory 3000 according to the present embodiment is described below with reference to FIGS. 10 to 12. FIGS. 10 to 12 schematically show manufacturing steps of the ferroelectric memory 3000 according to the present embodiment.

As shown in FIG. 10, the first sheet-shaped device 100 is formed on the substrate 10 as shown in FIG. 1 according to the manufacturing method in the first embodiment.

The second sheet-shaped device 110 is formed on a separation substrate 200 through a separation layer 202. As the material for the separation substrate 200, a material which transmits light such as laser light may be selected. For example, glass, a resin such as plastic, and the like can be given as such a material. The first and second sheet-shaped devices 100 and 110 are manufactured in the same manner as in the first embodiment.

As the material for the separation layer 202, a material which changes in properties and can be fused by application of light such as laser light, such as amorphous silicon, may be used. As the material for the separation layer 202, various substances such as an oxide such as silicon oxide, ceramic, an organic polymer compound, or a metal may be used in addition to amorphous silicon. As such substances, substances disclosed in Japanese Patent Application Laid-open No. 11-74533 may be used. In the case of using an organic polymer compound as the material for the separation layer 202, a polyolefin such as polyethylene or polypropylene, polyimide, polyamide, polyester, polymethylmethacrylate (PMMA), polyphenylene sulfide (PPS), polyether sulfone (PES), epoxy resin, or the like may be used.

As shown in FIG. 11, the first sheet-shaped device 100 and the second sheet-shaped device 110 formed on the separation substrate 200 through the separation layer 202 are bonded through the adhesive layer 204. As the adhesive layer 204, the above-described adhesive layer may be used.

The second sheet-shaped device 110 is separated from the separation substrate 200. The second sheet-shaped device 110 may be separated from the separation substrate 200 by causing the separation layer 202 to change in properties by applying light such as laser light 206 from the back side of the separation substrate 200, as shown in FIG. 11. In this case, as the material for the separation layer 202, a material which absorbs the applied laser light 206 and produces interlayer or interfacial separation by ablation may be used. There may be a case where gas is released from the separation layer 202 by application of the laser light 206 or the like, whereby the separation effect occurs. Specifically, there is a case where the component included in the separation layer 202 is gasified and released and a case where gas is released when the separation layer 202 absorbs light and contributes to separation. For example, separation at the separation layer 202 can be facilitated by mixing a substance which easily absorbs laser light (pigment, for example) or a substance which generates a gas due to light such as laser light or due to absorption heat of light such as laser light into the material for the separation layer 202.

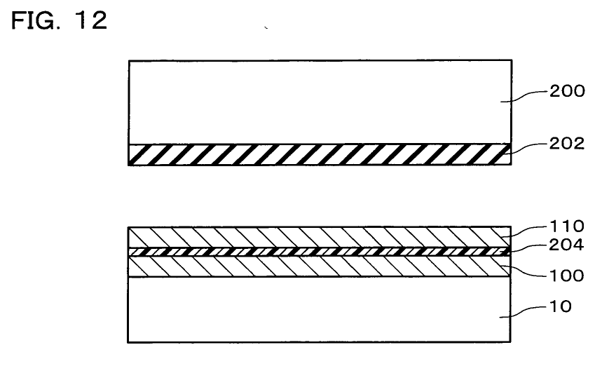

The second sheet-shaped device 110 is bonded to the substrate 10 as shown in FIG. 12, whereby the first sheet-shaped device 100 and the second sheet-shaped device 110 are stacked. A plurality of sheet-shaped devices can be stacked by repeatedly performing these steps.

In the ferroelectric memory 3000 according to the present embodiment, the sheet-shaped devices 100 and 110 may be bonded and electrically connected at the same time by forming bumps (not shown) on the ends of through-holes (not shown) formed in at least one of the sheet-shaped devices 100 and 110 when bonding the sheet-shaped devices 100 and 110 through the adhesive layer 204 in the step shown in FIG. 11.

According to the manufacturing method in the present embodiment, a plurality of sheet-shaped devices can be stacked. As a result, a ferroelectric memory in which an increase in the degree of integration can be realized by multilayering can be provided.

The present invention is not limited to the above-described embodiments. Various modifications and variations are possible within the spirit and scope of the present invention.

The above-described embodiments illustrate the case where two sheet-shaped devices are stacked. However, the present invention is not limited thereto. For example, three or more sheet-shaped devices may be stacked. The peripheral circuit section may be formed around the region in which the sheet-shaped devices are stacked in the same manner as in the modification of the first embodiment.

The sheet-shaped device may be formed on a flexible substrate by using the above-described technology of removing the sheet-shaped device. The flexible substrate is not particularly limited. A substrate exhibiting flexibility may be selected in order to increase applicability of the ferroelectric memory. Since the market for devices such as an IC card for which flexibility is required is expected to expand in the future, the application range can be increased in the field of the ferroelectric memory by providing the ferroelectric memory with flexibility. As examples of the material for the flexible substrate, a synthetic resin, a thin metal sheet, and the like can be given. In the case of selecting a substrate having no flexibility, a glass substrate or a semiconductor substrate may be used as the substrate.

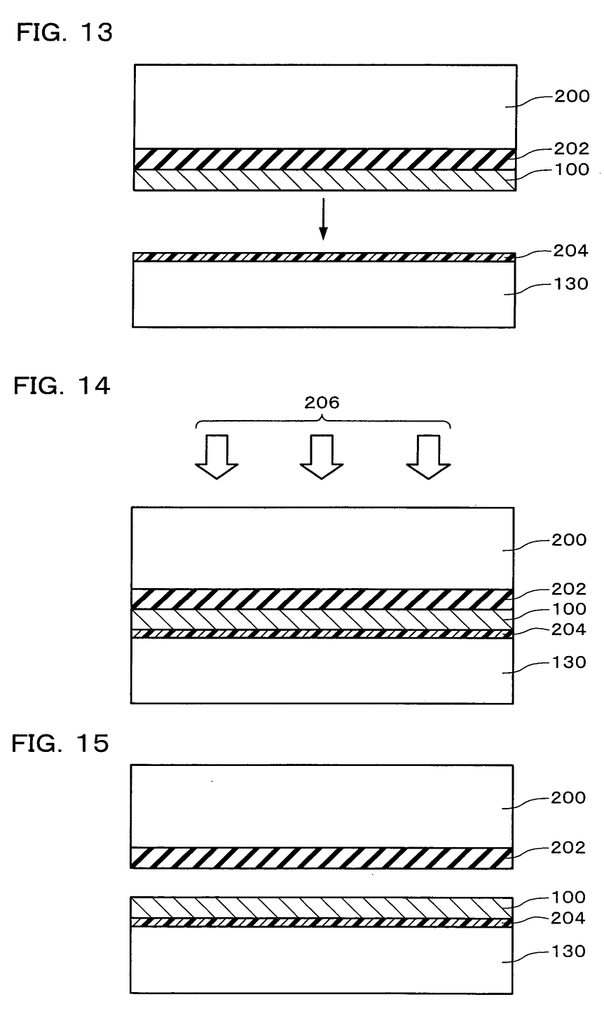

A method of manufacturing the ferroelectric memory according to this modification is described below with reference to FIGS. 13 to 15. The sheet-shaped device 100 is formed on the separation substrate 200 through the separation layer 202. A flexible substrate 130 on which the adhesive layer 204 is formed is provided. The sheet-shaped device 100 is bonded to the flexible substrate 130 through the adhesive layer 204. The sheet-shaped device 100 can be separated from the separation substrate 200 by causing the separation layer 202 to change in properties by applying the laser light 206 from the back side of the separation substrate 200. The adhesive layer 204 is not necessarily formed as a layer differing from the flexible substrate 130. The adhesive layer 204 may be integrally formed with the flexible substrate 130. This applies to the case where the sheet-shaped device 130 is caused to adhere to the flexible substrate 130 by thermocompression bonding utilizing surface properties of the flexible substrate 130, for example.

A plurality of sheet-shaped devices may be stacked, if necessary. This feature enables the sheet-shaped device to be used in wider applications.

1. A ferroelectric memory comprising a sheet-shaped device including a memory cell array which includes a ferroelectric capacitor, and a circuit section which is formed over the memory cell array and includes a thin-film transistor.

2. The ferroelectric memory as defined in claim 1, wherein a plurality of the sheet-shaped devices are stacked.

3. The ferroelectric memory as defined in claim 1, wherein a semiconductor layer of the thin-film transistor is a polysilicon layer.

4. The ferroelectric memory as defined in claim 1,
wherein the memory cell array includes a plurality of first electrodes which are arranged in lines, a plurality of second electrodes which intersect the first electrodes, and a ferroelectric layer which is disposed at least in each of intersecting regions of the first electrodes and the second electrodes.

5. The ferroelectric memory as defined in claim 1, further comprising a peripheral circuit section which is formed around the sheet-shaped device.

6. The ferroelectric memory as defined in claim 5, wherein the peripheral circuit section includes a thin-film transistor.

7. The ferroelectric memory as defined in claim 4, wherein the ferroelectric layer includes silicon and germanium in constituent elements at a ratio of 0≦germanium/silicon≦10.

8. The ferroelectric memory as defined in claim 2, wherein a semiconductor layer of the thin-film transistor is a polysilicon layer.

9. The ferroelectric memory as defined in claim 2,
wherein the memory cell array includes a plurality of first electrodes which are arranged in lines, a plurality of second electrodes which intersect the first electrodes, and a ferroelectric layer which is disposed at least in each of intersecting regions of the first electrodes and the second electrodes.

10. The ferroelectric memory as defined in claim 2, further comprising a peripheral circuit section which is formed around the sheet-shaped device.

11. The ferroelectric memory as defined in claim 10, wherein the peripheral circuit section includes a thin-film transistor.

12. The ferroelectric memory as defined in claim 9, wherein the ferroelectric layer includes silicon and germanium in constituent elements at a ratio of 0≦germanium/silicon≦10.

13. A method of manufacturing a ferroelectric memory, comprising:
(a) forming a memory cell array including a ferroelectric capacitor; and
(b) forming a circuit section including a thin-film transistor over the memory cell array to form a sheet-shaped device.

14. A method of manufacturing a ferroelectric memory, comprising:
(a) forming a separation layer which changes upon absorbing light on a first substrate which is capable of transmitting the light;
(b) forming a memory cell array and a circuit section on the separation layer to form a sheet-shaped device, the memory cell array including a ferroelectric capacitor, and the circuit section being disposed on the memory cell array and including a thin-film transistor;
(c) bonding the first substrate and a second substrate through at least an adhesive layer, the sheet-shaped device being formed on the first substrate; and
(d) removing the sheet-shaped device from the first substrate by applying light to the separation layer from one side of the first substrate.

15. The method of manufacturing a ferroelectric memory as defined in claim 14, comprising:
(e) bonding through an adhesive layer the sheet-shaped device that has been removed from the first substrate and another sheet-shaped device that is formed on a third substrate through a separation layer; and
(f) removing the third substrate by applying light from one side of the third substrate,
wherein a plurality of the sheet-shaped devices are stacked on the second substrate by repeatedly performing these steps one or more times.

16. The method of manufacturing a ferroelectric memory as defined in claim 13, comprising:
forming an insulating layer on the memory cell array, forming an amorphous silicon layer in a predetermined region of the insulating layer, and forming a polysilicon layer for the thin-film transistor by crystallizing the amorphous silicon layer by applying laser light, when forming the sheet-shaped device.

17. The method of manufacturing a ferroelectric memory as defined in claim 13, comprising:
forming first electrodes which are arranged in lines, a ferroelectric layer which is disposed above each of the first electrodes, and second electrodes which are disposed in lines above the ferroelectric layer and intersecting the first electrodes, when forming the memory cell array.

18. The method of manufacturing a ferroelectric memory as defined in claim 13, comprising:
forming a peripheral circuit section including a thin-film transistor around the sheet-shaped device.

19. The method of manufacturing a ferroelectric memory as defined in claim 17 wherein the ferroelectric layer includes silicon and germanium in constituent elements at a ratio of 0≦germanium/silicon≦10.

20. The method of manufacturing a ferroelectric memory as defined in claim 14, comprising:
forming an insulating layer on the memory cell array, forming an amorphous silicon layer in a predetermined region of the insulating layer, and forming a polysilicon layer for the thin-film transistor by crystallizing the amorphous silicon layer by applying laser light, when forming the sheet-shaped device.

21. The method of manufacturing a ferroelectric memory as defined in claim 14, comprising:
forming first electrodes which are arranged in lines, a ferroelectric layer which is disposed above each of the first electrodes, and second electrodes which are disposed in lines above the ferroelectric layer and intersecting the first electrodes, when forming the memory cell array.

22. The method of manufacturing a ferroelectric memory as defined in claim 14, comprising:
forming a peripheral circuit section including a thin-film transistor around the sheet-shaped device.

23. The method of manufacturing a ferroelectric memory as defined in claim 21, wherein the ferroelectric layer includes silicon and germanium in constituent elements at a ratio of 0≦germanium/silicon≦10.

24. The method of manufacturing a ferroelectric memory as defined in claim 15, comprising:
forming an insulating layer on the memory cell array, forming an amorphous silicon layer in a predetermined region of the insulating layer, and forming a polysilicon layer for the thin-film transistor by crystallizing the amorphous silicon layer by applying laser light, when forming the sheet-shaped device.

25. The method of manufacturing a ferroelectric memory as defined in claim 15, comprising:
forming first electrodes which are arranged in lines, a ferroelectric layer which is disposed above each of the first electrodes, and second electrodes which are disposed in lines above the ferroelectric layer and intersecting the first electrodes, when forming the memory cell array.

26. The method of manufacturing a ferroelectric memory as defined in claim 15, comprising:
forming a peripheral circuit section including a thin-film transistor around the sheet-shaped device.

27. The method of manufacturing a ferroelectric memory as defined in claim 25 wherein the ferroelectric layer includes silicon and germanium in constituent elements at a ratio of 0≦germanium/silicon≦10.
